(19) United States
(12) Patent Application Publication
(10) Pub. No.: US 2024/0055319 A1
(43) Pub. Date: Feb. 15, 2024

(54) CIRCUIT PACKAGE WITH IMPROVED THERMAL MANAGEMENT

(71) Applicant: Qorvo US, Inc., Greensboro, NC (US)

(72) Inventors: Matthew Irvine, Garland, TX (US); Dylan Murdock, Bend, OR (US)

(21) Appl. No.: 18/218,670

(22) Filed: Jul. 6, 2023

Related U.S. Application Data
(60) Provisional application No. 63/371,106, filed on Aug. 11, 2022.

(51) Int. Cl. H01L 23/373; H01L 23/00; H01L 23/367

(52) U.S. Cl. CPC H01L 23/3731; H01L 24/32; H01L 23/3675; H01L 24/73; H01L 2224/48155; H01L 2224/28; H01L 2924/141

(57) ABSTRACT

A circuit package with improved thermal management is disclosed. In one aspect, a ceramic insert is provided within a package having heat-producing circuitry thereon. The ceramic insert replaces traditional laminate inserts and provides a better thermal path to remove heat from leads and/or traces within the package. More particularly, the ceramic insert more readily transfers and/or dissipates heat that might otherwise accumulate at an output port where a solder junction may be made to couple the output port to external elements.

### PRIORITY APPLICATION

This application claims the benefit of U.S. Provisional Patent Application Ser. No. 63/371,106, filed on Aug. 11, 2022, the disclosure of which is hereby incorporated herein by reference in its entirety.

### BACKGROUND

### I. Field of the Disclosure

The technology of the disclosure relates generally to a package for integrated circuits (ICs) such as power amplifiers with a substrate designed to handle thermal cycling and high output power from the ICs.

### II. Background

Computing devices abound in modern society and have found their way into many systems and environments. One common application is wireless communication or wireless signaling, which may require power amplifiers to boost signals to desired levels. In personal mobile communication devices (e.g., cellular phones), such power amplifiers may be relatively small. Small power amplifiers may still generate relatively significant amounts of waste heat, but the position and packaging of such power amplifiers is currently adequate for managing such heat transitions. In larger systems, and particularly in many communication and radar systems, comparatively large power amplifiers may be used, with correspondingly larger demands for heat management during operation of such power amplifiers. When high power operation is sustained, there may be degradation and/or failure of the package. Such degradation or failure leaves room for innovation.

### SUMMARY

Aspects disclosed in the detailed description include a circuit package with improved thermal management. In particular, exemplary aspects of the present disclosure provide a ceramic insert within a package having heat-producing circuitry thereon. The ceramic insert replaces traditional laminate ringframes and provides a better thermal path to remove heat from leads and/or traces within the package. More particularly, the ceramic insert more readily transfers and/or dissipates heat that might otherwise accumulate at an output port where a solder junction may be made to couple the output port to external elements.

In this regard, in one aspect, a package is disclosed. The package comprises a base. The package also comprises a circuit mounted on the base. The circuit is coupled to a junction configured to couple to an external trace through an internal trace. The package also comprises a ceramic insert mounted on the base and spacing the junction from the base.

In another aspect, a structure is disclosed. The structure comprises a frame structure comprising an external trace. The structure also comprises a package mounted in the frame structure. The package comprises a base. The package also comprises a circuit mounted on the base. The circuit is coupled to a junction configured to couple to the external trace through an internal trace. The package also comprises a ceramic insert mounted on the base and spacing the junction from the base.

### BRIEF DESCRIPTION OF THE DRAWINGS

FIG. 1A is a perspective view of a package carrying heat-generating circuitry within a larger structure, illustrating how the package may be coupled to traces so that the circuitry may be coupled to external elements;

FIG. 1B is a perspective view of the package removed from the larger structure;

FIG. 2 is a top plan view of the package with lid removed showing internal heat-generating circuitry and the junction of internal traces coupling to external traces; and

FIG. 3 is a side elevational cross-sectional view of the package of FIG. 2, showing the trace junction relative to the ceramic insert of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects disclosed in the detailed description include a circuit package with improved thermal management. In particular, exemplary aspects of the present disclosure provide a ceramic insert within a copper package having heat-producing circuitry thereon. The ceramic insert replaces traditional laminate inserts and provides a better thermal path to remove heat from leads and/or traces within the package. More particularly, the ceramic insert more readily transfers and/or dissipates heat that might otherwise accumulate at an output port where a solder junction may be made to couple the output port to external elements.

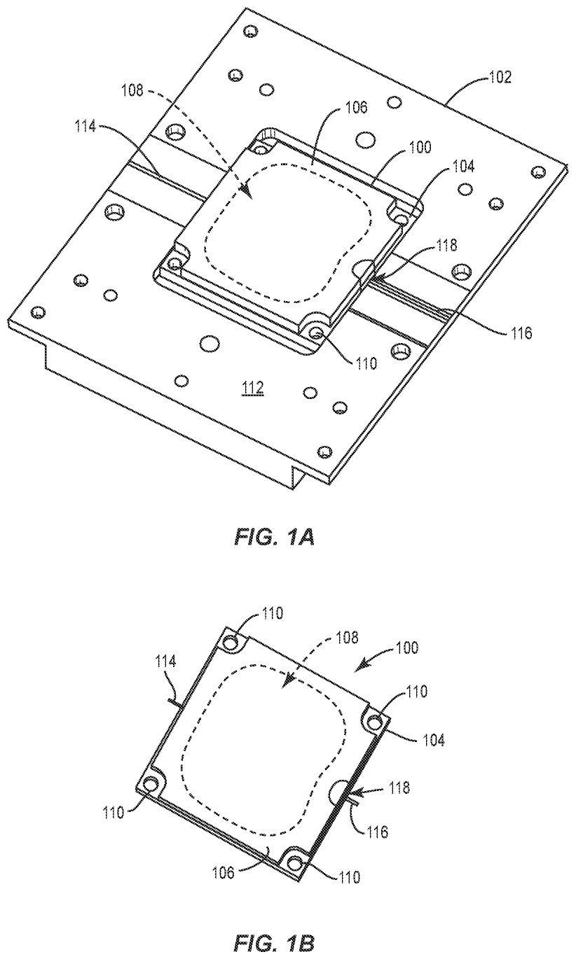

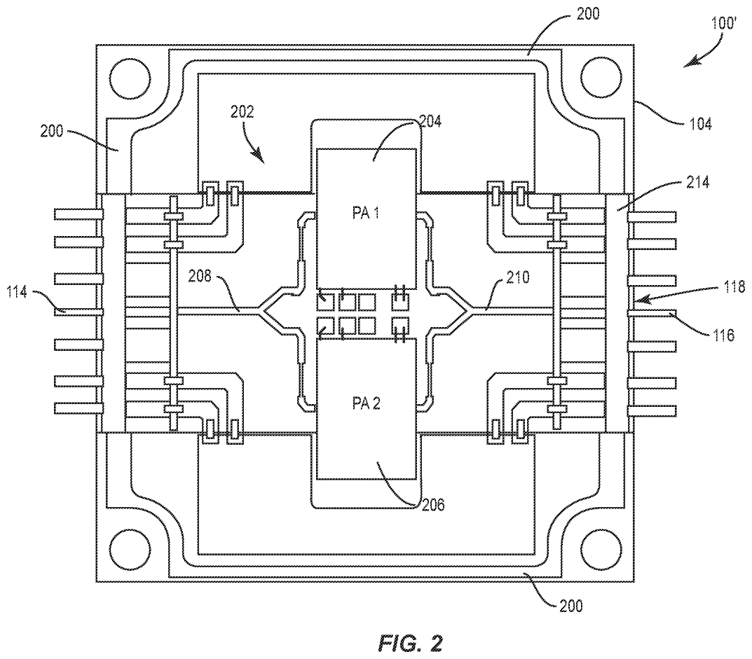

In this regard, FIG. 1A is a perspective view of a package 100 according to the present disclosure mounted in another frame structure 102. FIG. 1B illustrates the package 100 removed from the frame structure 102. As better seen in FIG. 1B, but also illustrated in FIG. 1A, the package 100 may include a base 104 and a lid 106. An air cavity 108 is present between the base 104 and the lid 106 and may contain circuitry therein (as explained in greater detail below with reference to FIG. 2). In an exemplary aspect, the base 104 may be a copper carrier for the circuits positioned thereon. Other materials may also be used, including, but not limited to, conductive metals, copper alloys, metal ceramic composites or hybrids, copper diamond materials, aluminum diamond materials, layered copper composites, aluminum matrix with silicon carbide particles (AlSiC, sometimes referred to as “alsick”), or the like.

The base 104 may delimit apertures 110 through which a means for attaching may pass so as to attach the package 100 to the frame structure 102. The means for attaching (not illustrated) may be rivets, screws, bolts, or the like. Other means such as soldering, bonding, clamping, compressing, or the like may also be used, in which case apertures 110 may be present or omitted. The base 104 may be generally co-planar with and abut a top surface 112 of the frame structure 102.

A first external trace 114 may provide a conductive path to carry, for example, a signal to be amplified across the top surface 112 to the package 100. A second external trace 116 may provide a conductive path to carry, for example, an amplified signal across the top surface 112 from the package 100. While not illustrated, it should be appreciated that other external traces may be present and couple to the package 100. Likewise, external traces, including the external traces 114, 116 may be embedded into the frame structure 102 (e.g., as part of a metal layer within a laminate or the like). Likewise, the external traces 114, 116 may not carry signals to be amplified/amplified signals but may carry other sorts of signals (e.g., control signals, data signals, clock signals, or the like).

When the external trace 116 carries a signal, an interconnect or junction 118 where the external trace 116 couples to the base 104 may be formed by using a solder material or the like. It is not uncommon, particularly where the external trace 116 carried an amplified signal, for the junction 118 to generate waste heat. The junction 118 may be formed through solder, through wire bonds, or the like, although in an exemplary aspect, solder is used most prevalently.

In the absence of the present disclosure, such waste heat may generate sufficient heat to cause the solder material to melt and reflow, potentially causing an undesired short circuit to another trace, an open circuit, or otherwise materially degrade the conductive path between circuitry within the package 100 and the external trace 116.

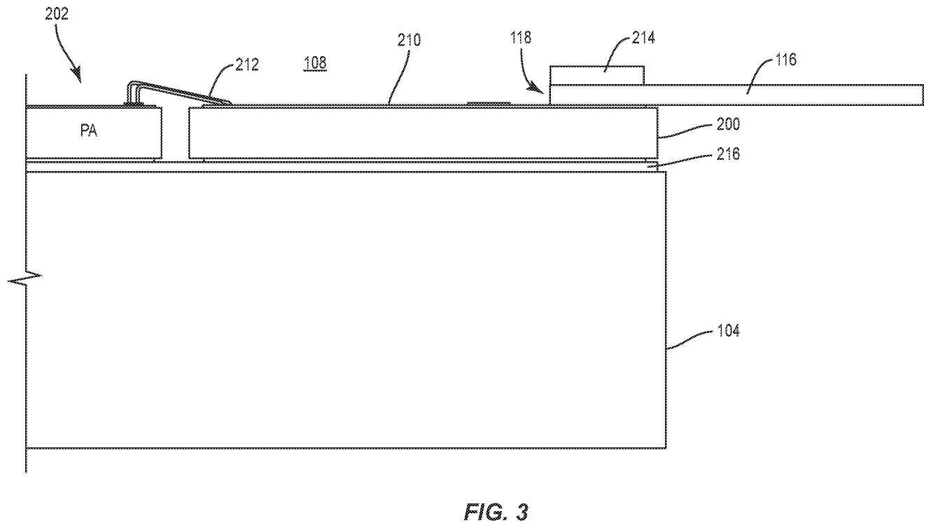

Exemplary aspects of the present disclosure provide a ceramic insert 200 better illustrated in FIGS. 2 and 3, which is positioned in close proximity to the junction 118 and acts as a heat sink to prevent the heat bloom 120 from causing damage to the junction 118.

In this regard, FIGS. 2 and 3 illustrate a portion 100′ of the package 100, and specifically illustrate the package 100 without the lid 106. Circuits 202, which may, for example, be a first power amplifier 204 and a second power amplifier 206, may be coupled to the first external trace 114 by a first internal trace 208. The circuits 202 may further be coupled to the second external trace 116 by a second internal trace 210. In an exemplary aspect, the circuits 202 may be coupled to the traces 208, 210 by wire bonds 212 (FIG. 3). Note that other internal traces (not labeled) may be coupled to other external traces at corresponding junctions (not labeled). Any of these circuits and/or junctions may generate waste heat. A cover strip 214 may cover the junctions.

The ceramic insert 200 may be a ringframe and may substantially circumscribe the air cavity 108 and may conform to the shape of the lid 106 so that the lid 106 may attach to the ceramic insert 200. For example, if the lid 106 has scalloped corners to accommodate the apertures 110, then the ceramic insert 200 may also include scalloped corners. Note that the scalloped corners may not be present in all configurations and may be present, for example, to accommodate certain types of attachment means. Further note, however, that the lid 106 may attach directly to the base 104. In still other exemplary aspects, the lid 106 may concurrently attach to the base 104 and the ceramic insert 200. While the ceramic insert 200 may be a ringframe, other exemplary aspects may not completely encircle the package and thus may not properly be a “ringframe.” The ceramic insert 200 may be attached to the base 104 using an adhesive such as an epoxy or more specifically, a low modulus epoxy 216 (FIG. 3). The low modulus epoxy 216 may compensate for a large coefficient of thermal expansion (CTE) mismatch between the base 104 and the ceramic insert 200. Note that while a low modulus epoxy 216 is specifically contemplated, other materials such as other epoxies, solders, brazing or the like may be used to attach the insert 200 to the base 104, and may generically be referred to as insert attach material.

In an exemplary aspect, the ceramic insert 200 may be formed from a material having a high thermal conductivity. One example of a ceramic material is formed from a material that is aluminum oxide (Al₂O₃) or aluminum nitride (AlN). The ceramic insert 200 forms an effective thermal path for heat generated at the junction 118 to pass into the base 104 and from the base 104 to a heat sink in the frame structure 102 or other location.

In further exemplary aspects, it should be appreciated that the package 100 may be approximately 0.2 inches (in) to 5 inches on a side (i.e., 0.508 cm to 12.7 cm). The circuits 202 may include a single monolithic device or may be multiple devices. Exemplary use cases include radar applications including aerospace and/or weather radar type applications. Testing shows that the use of such a ceramic insert 200 may allow operation at frequencies up through at least 40 gigahertz (GHz) and potentially higher, although larger impacts will generally be felt at higher frequencies. Likewise, power levels at the junction 118 have been tested up to 175 watts (W) (depending on frequency) and may tolerate higher power levels without failure.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

What is claimed is:

1. A package comprising:
a base;
a circuit mounted on the base, the circuit coupled to a junction configured to couple to an external trace through an internal trace; and
a ceramic insert mounted on the base and spacing the junction from the base.

2. The package of claim 1, wherein the circuit comprises a power amplifier.

3. The package of claim 1, wherein the circuit comprises a plurality of power amplifiers.

4. The package of claim 1, wherein the base comprises a metal material.

5. The package of claim 1, wherein the base comprises a ceramic metal composite material.

6. The package of claim 1, further comprising a lid configured to be attached to the ceramic insert.

7. The package of claim 1, further comprising a lid configured to be attached to the ceramic insert and the base concurrently.

8. The package of claim 1, wherein the junction comprises an output port for the package.

9. The package of claim 1, wherein the junction comprises a wire bond configured to attach the internal trace to the external trace.

10. The package of claim 1, wherein the junction comprises a solder configured to attach the internal trace to the external trace.

11. The package of claim 1, wherein the ceramic insert comprises aluminum oxide (Al₂O₃).

12. The package of claim 1, wherein the ceramic insert comprises aluminum nitride (AlN).

13. The package of claim 1, wherein the ceramic insert is attached to the base through an epoxy.

14. The package of claim 1, wherein the ceramic insert is attached to the base through solder.

15. The package of claim 1, wherein the ceramic insert is attached to the base through brazing.

16. The package of claim 1, wherein the ceramic insert is attached to the base through an adhesive.

17. The package of claim 1, further comprising a cover strip covering the junction.

18. A structure comprising:
a frame structure comprising an external trace; and
a package mounted in the frame structure, the package comprising:
a base;
a circuit mounted on the base, the circuit coupled to a junction configured to couple to the external trace through an internal trace; and
a ceramic insert mounted on the base and spacing the junction from the base.

19. The structure of claim 18, wherein the base comprises a metal material.

20. The structure of claim 18, further comprising a cover strip covering the junction.
